(19) United States
(12) Patent Application Publication
(10) Pub. No.: US 2026/0305224 A1
(43) Pub. Date: Oct. 1, 2026

(54) SUBSTRATE PROCESSING APPARATUS AND SUBSTRATE PROCESSING METHOD

(71) Applicant: SHIBAURA MECHATRONICS CORPORATION, Yokohama-shi (JP)

(72) Inventors: Keisuke TSUSHIMA, Yokohama-shi (JP); Takahiro KANAI, Yokohama-shi (JP)

(73) Assignee: SHIBAURA MECHATRONICS CORPORATION, Yokohama-shi (JP)

(21) Appl. No.: 19/562,690

(22) Filed: Mar. 10, 2026

(30) Foreign Application Priority Data
Mar. 31, 2025 (JP) 2025-059775

(51) Int. Cl. H10P 72/00; H10P 72/76

(52) U.S. Cl. CPC H10P 72/0414; H10P 72/0434; H10P 72/7618

(57) ABSTRACT

A substrate processing apparatus according to an embodiment includes a rotary holding portion including a holding portion for holding a substrate and a rotary body having an upper surface facing a bottom surface of the substrate held by the holding portion, the rotary holding portion rotating the substrate by rotating the holding portion and the rotary body, a first gas supply portion for supplying a first gas for cooling into a space between the upper surface of the rotary body and the substrate held by the holding portion, a first liquid supply portion for supplying a first liquid to the substrate held by the holding portion, and a second liquid supply portion for supplying a second liquid having a temperature of 0° C. or higher to the upper surface of the rotary body.

### CROSS-REFERENCE TO RELATED APPLICATIONS

This application claims the benefit of priority to Japanese Patent Application No. 2025-059775, filed on Mar. 31, 2025, the entire contents of which are incorporated herein by reference.

### BACKGROUND

### Technical Field

The present disclosure relates to a substrate processing apparatus and a substrate processing method.

### Description of the Related Art

A freeze cleaning method is known as one method of removing and cleaning foreign matter such as particles adhering to a surface to be processed of a substrate such as an imprint template, a mask for photolithography, or a semiconductor wafer.

In the freeze cleaning method, various liquids can be used as the liquid used for washing. In the case where pure water is used for cleaning, pure water is first supplied to the surface to be processed of the rotated substrate. Next, the supply of pure water is stopped, and a part of the supplied pure water is discharged from the substrate to form a liquid film of pure water on the surface to be processed of the substrate. The liquid film is frozen by a cooling gas supplied to the substrate. When the liquid film is frozen and becomes a frozen body (ice), foreign matter such as particles are taken into the frozen body and are separated from the surface of the substrate. Then, pure water is supplied to the frozen liquid film to be melted, and the foreign matter are removed from the substrate together with the pure water.

When the cooling gas is supplied to the substrate, not only the substrate but also a rotary body such as a rotary table that rotates together with the substrate is cooled. When the rotary body is cooled and the temperature is lowered, the surrounding atmosphere is cooled by the cooled rotary body, so that dew condensation may occur on a surface of the rotary body and surrounding members. Liquid generated by the dew condensation is further cooled, frozen, and becomes a frozen body. When this frozen body occurs between the rotary body and the non-rotary member, the rotation of the rotary body is hindered, which causes a rotation failure. Further, when the frozen body is formed around a holding portion holding the substrate, an operation for holding the substrate W is hindered, which causes a holding failure of the substrate W.

### BRIEF SUMMARY

A substrate processing apparatus according to an embodiment includes a rotary holding portion including a holding portion for holding a substrate and a rotary body having an upper surface facing a bottom surface of the substrate held by the holding portion, the rotary holding portion rotating the substrate by rotating the holding portion and the rotary body, a first gas supply portion for supplying a first gas for cooling into a space between the upper surface of the rotary body and the substrate held by the holding portion, a first liquid supply portion for supplying a first liquid to the substrate held by the holding portion, and a second liquid supply portion for supplying a second liquid having a temperature of 0° C. or higher to the upper surface of the rotary body.

A substrate processing method according to an embodiment includes holding a substrate with a liquid film formed on an upper surface of the substrate so that the substrate faces an upper surface of a rotary body, supplying a first gas for cooling into a space between the upper surface of the rotary body and the substrate, thereby freezing at least a portion of the liquid film into a frozen body, and supplying liquid onto the upper surface of the rotary body to raise a temperature of the upper surface of the rotary body.

### BRIEF DESCRIPTION OF THE SEVERAL VIEWS OF THE DRAWINGS

FIG. 1 is a side view showing a schematic configuration of a substrate processing apparatus according to a first embodiment.

FIG. 2 is a side cross-sectional view showing a schematic configuration of a main part of the substrate processing apparatus according to the first embodiment.

FIG. 3 is a plan view showing a schematic configuration of a main part of the substrate processing apparatus according to the first embodiment.

FIG. 4 is a flowchart showing an operation of the substrate processing apparatus according to the first embodiment.

FIG. 5 is a flowchart showing an operation of the substrate processing apparatus according to the first embodiment.

FIG. 6 is a side cross-sectional view showing a schematic configuration of a substrate processing apparatus according to a second embodiment.

FIG. 7 is a flowchart showing an operation of the substrate processing apparatus according to the second embodiment.

### DETAILED DESCRIPTION

Hereinafter, a substrate processing apparatus according to an embodiment of the present disclosure will be described with reference to the drawings. In the specification and claims of the present application, “upper” indicates a direction away from an installation surface (for example, a floor surface of a factory) of the substrate processing apparatus in a state in which normal use is possible, and “lower” indicates a direction opposite to “upper”.

### First Embodiment

A substrate processing apparatus for cleaning a semiconductor substrate (for example, a semiconductor wafer) will be described as an example of a substrate processing apparatus according to an embodiment of the present disclosure. However, the substrate to be processed is not limited to a semiconductor wafer, and other substrates may be processed. For example, a plate-like member used for an imprint template, a mask for photolithography, or a MEMS (Micro Electro Mechanical Systems) may be used as a substrate to be processed.

### Configuration of Substrate Processing Apparatus

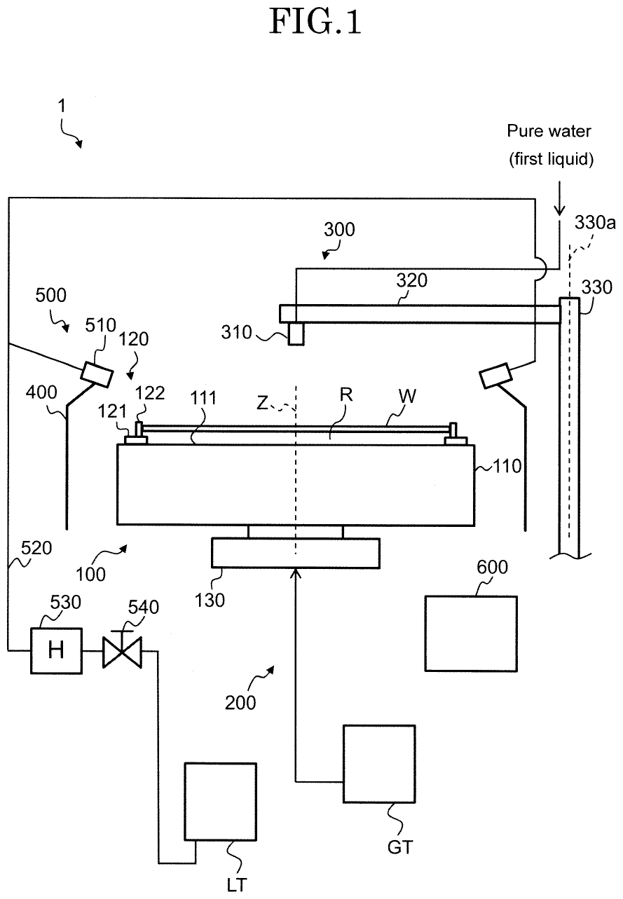

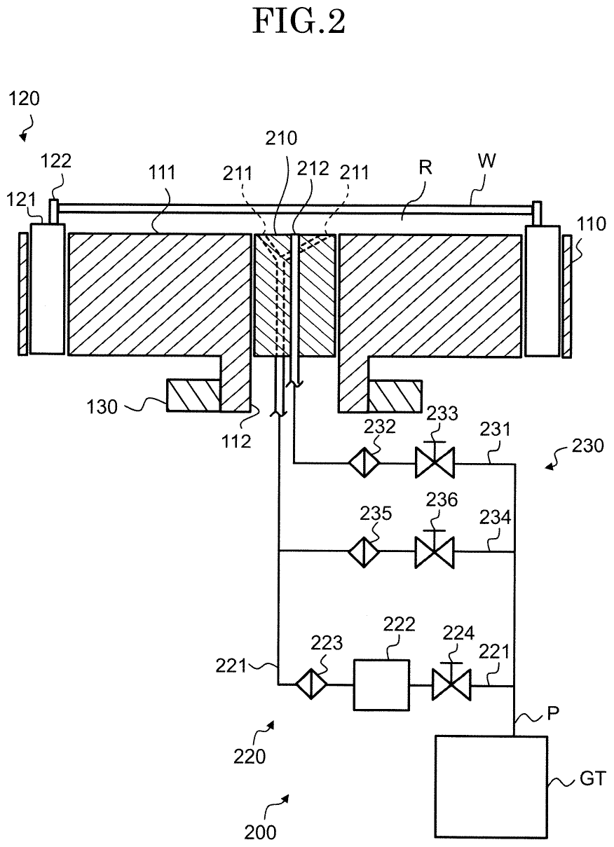

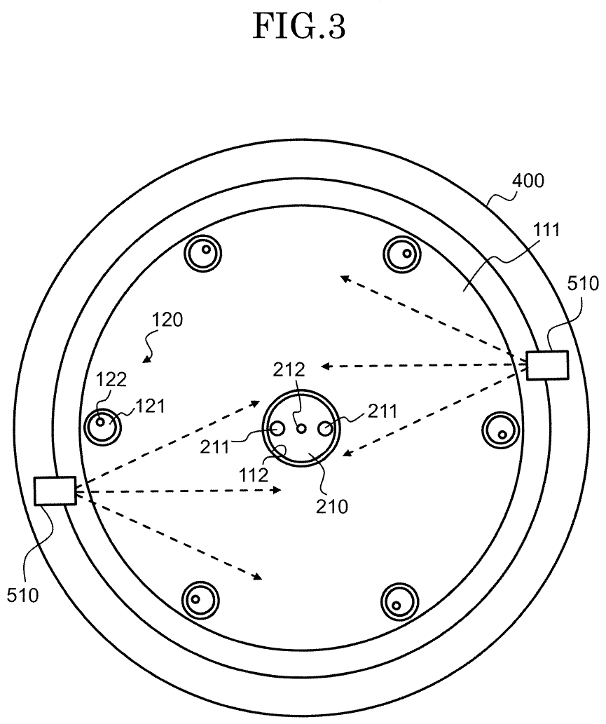

A configuration of a substrate processing apparatus 1 according to a first embodiment will be described with reference to FIG. 1 to FIG. 3. FIG. 1 is a side view showing a schematic configuration of the substrate processing apparatus 1 according to the first embodiment. FIG. 2 is a side cross-sectional view showing a schematic configuration of a main part of the substrate processing apparatus 1 according to the first embodiment. FIG. 3 is a plan view showing a schematic configuration of a main part of the substrate processing apparatus 1 according to the first embodiment. The substrate processing apparatus 1 is an apparatus that performs a cleaning process by a freeze cleaning method on a substrate W to be processed. FIG. 1 and FIG. 2 show a state in which the substrate W is held, and FIG. 3 shows a state in which the substrate W is not held.

The substrate processing apparatus 1 includes a rotary holding portion 100, a gas supply portion 200, a first liquid supply portion 300, a collecting portion 400, a second liquid supply portion 500, and a control device 600. The substrate processing apparatus 1 holds the loaded substrate W by the rotary holding portion 100. Further, a liquid film is frozen by cooling the substrate W on which the liquid film is formed by a first gas (cooling gas) supplied by the gas supply portion 200. Thereafter, by supplying a liquid onto the substrate W, the frozen liquid film is melted and then discharged from the substrate W, thereby the substrate W is cleaned.

### Rotary Holding Portion

The rotary holding portion 100 includes a rotary body 110, a holding portion 120, and a drive portion 130. The rotary holding portion 100 holds the substrate W and rotates the held substrate W with an axis Z extending in a vertical direction as a rotation axis.

The rotary body 110 is a rotary body that is rotatably provided and supports the holding portion 120. The rotary body 110 has a substantially circular outer shape in a plan view, and a diameter of an upper surface 111 thereof is larger than a diameter of the substrate W. The upper surface 111 of the rotary body 110 is an opposing surface opposed to a lower surface of the substrate W held by the holding portion 120 with a space therebetween. A through hole 112 (see FIG. 2) is formed in a central portion of the rotary body 110. The through hole 112 is a hole formed in the rotary body 110 so as to penetrate in the up-down direction. A nozzle head 210, which will be described later, is inserted into the through hole 112.

The holding portion 120 is a member that holds the substrate W. The holding portion 120 is, for example, a chuck pin, and a plurality of holding portions is provided along an outer periphery of the substrate W to be held. The holding portion 120 has a cylindrical support portion 121 extending in the up-down direction and configured to be rotatable, and a pin portion 122 arranged so as to protrude from an upper end of the support portion 121. The support portion 121 is configured to be rotatable by a drive mechanism (not shown) with its center as a rotation axis. The pin portion 122 is arranged at a position deviated from the rotation axis of the support portion 121 in a plan view. As a result, when the support portion 121 rotates about its center as a rotation axis, the pin portion 122 can move inward and contact an outer peripheral portion of the substrate W to hold the substrate W. Further, when the support portion 121 is reversely rotated, the pin portion 122 moves outward and moves away from the outer peripheral portion of the substrate W, thereby releasing the substrate W.

The drive portion 130 is a driving mechanism that rotates the rotary body 110. The drive portion 130 rotates the substrate W by rotating the rotary body 110. The drive portion 130 is rotatably supported by a frame (not shown) and is connected to a lower end side of the rotary body 110.

### Gas Supply Portion

The gas supply portion 200 includes the nozzle head 210, a first gas supply portion 220, and a second gas supply portion 230. The gas supply portion 200 supplies the first gas or a second gas from a discharge port formed in the nozzle head 210 to a space R located between the upper surface 111 of the rotary body 110 and the substrate W held by the holding portion 120. In the present embodiment, the first gas and the second gas are both nitrogen gas and have different temperatures. The first gas is a gas for cooling the substrate W, and is, for example, nitrogen gas cooled by a cooling device. The temperature of the first gas is, for example, −120° C. The gas supply portion 200 cools the substrate W by supplying the first gas to the space R. The second gas is a gas for drying the upper surface 111 of the rotary body 110 and an upper surface of the nozzle head 210. The second gas is a gas that has not undergone an intentional cooling operation, and is, for example, a nitrogen gas at room temperature. The gas supply portion 200 supplies the second gas to the space R, thereby removing a liquid adhering to the upper surface 111 of the rotary body 110 and the upper surface of the nozzle head 210 and drying the liquid. In the present embodiment, the normal temperature is an environmental temperature in a factory in which the substrate processing apparatus 1 is installed, and is usually 20° C. to 25° C.

The nozzle head 210 is a member in which a discharge port for discharging the first gas or the second gas is formed with respect to the space R between the upper surface 111 of the rotary body 110 and the substrate W held by the holding portion 120. The nozzle head 210 is inserted into the through hole 112 of the rotary body 110, and the upper surface thereof is exposed. That is, in the present embodiment, the space R also includes a space between the upper surface of the nozzle head 210 and the substrate W held by the holding portion 120. The nozzle head 210 is fixed to a frame (not shown) and is not in contact with an inside of the through hole 112 of the rotary body 110. Thus, even if the rotary body 110 rotates, the nozzle head 210 does not rotate.

A first discharge port 211 and a second discharge port 212 are formed in the nozzle head 210. The first discharge port 211 is an opening formed at a position deviated from a center of the nozzle head 210 in a plan view. In the present embodiment, two first discharge ports 211 are formed so as to sandwich the center of the nozzle head 210. In addition, the first discharge port 211 is formed so as to be inclined toward the outside as it goes upward. As a result, the gas supplied from the first discharge port 211 to the space R is discharged toward an outer peripheral side of the substrate W. In addition, in FIG. 2, although inclination angles of the two first discharge ports 211 are different for convenience of illustration, the inclination angles may be the same.

The second discharge port 212 is an opening formed in the center of the nozzle head 210 in a plan view. As a result, the gas supplied from the second discharge port 212 to the space R is discharged toward a center of the substrate W. The gas discharged toward the center of the substrate W then flows to an outer peripheral side of the substrate W along the lower surface of the substrate W.

The first gas supply portion 220 is a mechanism for supplying the first gas to the space R. The first gas supply portion 220 supplies the first gas to the first discharge port 211 to discharge the first gas from the first discharge port 211. The first gas supply portion 220 includes a first piping 221, a cooling device 222, a removal portion 223, and a valve 224.

The first piping 221 is a piping that serves as a flow path for sending a gas from a gas source GT such as a tank in which a gas (nitrogen gas) is stored to the first discharge port 211. One end of the first piping 221 is connected to a common piping P extending from the gas source GT. The other end of the first piping 221 is connected to the first discharge port 211. As shown in FIG. 2, a part of the first piping 221 is formed by passing through the nozzle head 210. In addition, in the present embodiment, in order to send the gas to the two first discharge ports 211, the first piping 221 branches into two in the nozzle head 210. That is, the first piping 221 of the present embodiment is also a piping that distributes the gas sent from the gas source GT to the two first discharge ports 211.

The cooling device 222 is a device that cools the gas sent from the gas source GT. The cooling device 222 is arranged in the middle of the first piping 221. The cooling device 222 is, for example, a chiller. The gas that has passed through the cooling device 222 is cooled to become a first gas.

The removal portion 223 is a filter or the like for removing foreign matter contained in the gas passing therethrough. The removal portion 223 is arranged in the middle of the first piping 221 and on a downstream side of the cooling device 222 in a direction in which the gas flows. That is, the removal portion 223 removes foreign matter contained in the first gas.

The valve 224 is a valve body that switches between discharging and stopping the discharge of the first gas. The valve 224 is arranged in the middle of the first piping 221 and an upstream side of the cooling device 222 in the direction in which the gas flows. By opening the valve 224, the gas delivered from the gas source GT passes through the cooling device 222 and is discharged from the first discharge port 211 as the first gas. By closing the valve 224, the delivery of the gas from the gas source GT to the first piping 221 is blocked, and the discharge of the first gas from the first discharge port 211 is stopped.

The second gas supply portion 230 is a mechanism for supplying the second gas to the space R. The second gas supply portion 230 supplies the second gas to the second discharge port 212 to discharge the second gas from the second discharge port 212. Further, the second gas supply portion 230 supplies the second gas to the first discharge port 211 and also discharges the second gas from the first discharge port 211. The second gas supply portion 230 includes a second piping 231, a removal portion 232, a valve 233, a third piping 234, a removal portion 235, and a valve 236.

The second piping 231 is a piping that serves as a flow path for sending a gas from a gas source GT such as a tank in which a gas (nitrogen gas) is stored to the second discharge port 212. One end of the second piping 231 is connected to a common piping P extending from the gas source GT. That is, the first piping 221 and the second piping 231 branch from the common piping P. The other end of the second piping 231 is connected to the second discharge port 212. In addition, as shown in FIG. 2, a part of the second piping 231 is formed by passing through the center of the nozzle head 210.

As described above, in the present embodiment, the second gas is not subjected to an intentional cooling operation. Therefore, the second gas can be discharged from the second discharge port 212 by supplying the gas sent from the gas supply source GT to the second discharge port 212 without changing the temperature. For example, by supplying the normal temperature gas sent from the gas supply source GT to the second discharge port 212, the normal temperature second gas can be discharged from the second discharge port 212.

The removal portion 232 is a filter or the like for removing foreign matter contained in the gas passing therethrough. The removal portion 232 is arranged in the middle of the second piping 231.

The valve 233 is a valve element that switches between discharging and stopping the discharge of the second gas from the second discharge port 212. The valve 233 is arranged in the middle of the second piping 231 and an upstream side of the removal portion 232 in a direction in which the gas flows. By opening the valve 233, the gas (second gas) delivered from the gas source GT is discharged from the second discharge port 212. By closing the valve 233, the delivery of the gas from the gas source GT to the second piping 231 is blocked, and the discharge of the second gas from the second discharge port 212 is stopped. Further, a flow rate of the second gas discharged from the second discharge port 212 can be changed according to a degree of opening of the valve 233. The flow rate of the second gas discharged from the second discharge port 212 may be changed by providing a flow rate adjustment mechanism in the middle of the second piping 231 separately from the valve 233.

The third piping 234 serves as a flow path for sending a gas from a gas source GT such as a tank in which a gas (nitrogen gas) is stored to the first discharge port 211. One end of the third piping 234 is connected in the middle of the second piping 231 so as to branch from a position upstream of the valve 233 in a direction in which the gas flows. The other end of the third piping 234 is connected to a downstream side of the removal portion 223 in the middle of the first piping 221 in the direction in which the gas flows. That is, the third piping 234 is provided so that the gas sent from the gas supply source GT can be supplied to the first discharge port 211 without passing through the cooler 222. By supplying the gas sent from the gas supply source GT to the first discharge port 211 without changing the temperature, the second gas can be discharged from the first discharge port 211. For example, by supplying the normal temperature gas sent from the gas source GT to the first discharge port 211, the normal temperature second gas can be discharged from the first discharge port 211. However, in the case where the first gas (cooling gas) is discharged from the first discharge port 211, the temperature of the nozzle head 210 decreases. Therefore, the second gas discharged into the space R may have a temperature lower than the normal temperature, particularly at the beginning of its discharge.

The removal portion 235 is a filter or the like for removing the gas contained in the gas passing therethrough. The removal portion 235 is arranged in the middle of the third piping 234.

The valve 236 is a valve element that switches between discharging and stopping the discharge of the second gas from the first discharge port 211. The valve 236 is arranged in the middle of the third piping 234 and on an upstream side of the removal portion 235 in a direction in which the gas flows. By opening the valve 236, the gas (second gas) delivered from the gas source GT is discharged from the first discharge port 211. By closing the valve 236, the delivery of the gas from the gas source GT to the third piping 234 is blocked, and the discharge of the second gas from the first discharge port 211 is stopped. Further, a flow rate of the second gas discharged from the first discharge port 211 can be changed according to a degree of opening of the valve 236. The flow rate of the second gas discharged from the first discharge port 211 may be changed by providing a flow rate adjustment mechanism in the middle of the third piping 234 separately from the valve 236.

### First Liquid Supply Portion

The first liquid supply portion 300 includes a discharge nozzle 310, an arm 320, and a support pillar 330. The first liquid supply portion 300 supplies a first liquid that is a cleaning liquid to the upper surface of the substrate W. For example, pure water, a liquid containing water as a main component, or the like can be used as the first liquid. In the present embodiment, pure water is used as the first liquid.

The discharge nozzle 310 (first liquid discharge nozzle) discharges the first liquid toward the upper surface of the substrate W held by the holding portion 120. The first liquid is supplied to the discharge nozzle 310 from a tank or the like in which the first liquid is stored. The discharge nozzle 310 discharges the supplied first liquid.

The arm 320 is a rod-shaped member extending in the horizontal direction. A discharge nozzle 310 is fixed to a tip of the arm 320, and supports the discharge nozzle 310. The support pillar 330 is a columnar member extending in the vertical direction. The support pillar 330 supports the arm 320 and is rotatably provided with a shaft 330a as a rotation axis. The support pillar 330 is rotated by driving of a drive mechanism (not shown), thereby the arm 320 is rotated. By the rotation of the arm 320, the discharge nozzle 310 fixed to the tip of the arm 320 moves between a supply position above the substrate W held by the holding portion 120 and a retreat position, which is a position deviated from an upper part of the rotary holding portion 100. FIG. 1 shows the discharge nozzle 310 in the supply position.

### Collecting Portion

The collecting portion 400 receives and collects the liquid discharged from the upper surface of the substrate W. The collecting portion 400 of the present embodiment also receives and collects the liquid discharged from the upper surface 111 of the rotary body 110. The collecting portion 400 has a cylindrical shape and surrounds the rotation holding portion 100. Further, the upper portion of the collecting portion 400 is inclined toward a radially inner side. The liquid received by the collecting portion 400 falls downward along an inner wall of the collecting portion 400 and is discharged to the outside of the substrate processing apparatus 1 through a discharge port (not shown).

The collecting portion 400 is provided to be movable up and down by an elevating mechanism (not shown) to a collection position for receiving the liquid discharged from the upper surface of the substrate W and a retreat position for moving downward to carry out and carry in the substrate W. The collection position is a position where an upper end of the collecting portion 400 is higher than a height of the upper surface of the substrate W held by the holding portion 120, and the retreat position is a position where the upper end of the collecting portion 400 is equal to or lower than a height of the upper surface 111 of the rotary body 110.

### Second Liquid Supply Portion

The second liquid supply portion 500 includes a nozzle 510, a supply piping 520, a heating portion 530, and a valve 540. The second liquid supply portion 500 supplies the second liquid to the upper surface 111 of the rotary body 110, thereby raising the temperature of the rotary body 110. The second liquid is a liquid at 0° C. or higher. The temperature of the second liquid is preferably at or above room temperature and below the boiling point of the second liquid, more preferably from 40° C. to 60° C. The second liquid may be, for example, pure water or hot water (hot pure water). In the present embodiment, the second liquid supplied to the upper surface 111 of the rotary body 110 is hot water at 50° C.

The nozzle 510 (second liquid discharge nozzle) is a nozzle that discharges the second liquid toward the upper surface 111 of the rotary body 110. In the present embodiment, two nozzles 510 are provided. The nozzle 510 is fixed to the upper end of the collecting portion 400, and a tip of the nozzle 510 faces obliquely downward so as to discharge the second liquid toward the inside of the collecting portion 400. Further, as shown in FIG. 3, the two nozzles 510 are provided so as to be rotationally symmetrical about the nozzle head 210.

The nozzle 510 of the present embodiment includes a nozzle tip (discharge port) that discharges the liquid so as to expand in a fan shape. The nozzle 510 is fixed in such a direction that the liquid spreads in the horizontal direction. That is, the liquid discharged from the nozzle 510 is directed obliquely downward while spreading in the horizontal direction. Further, as shown in FIG. 3, a central axis (an axis in a discharge direction) of the nozzle 510 is directed toward the upper surface 111 of the rotary body 110. That is, the center axis of the nozzle 510 is provided so as to be directed to a position deviated from the nozzle head 210. FIG. 3 shows a state where the collecting portion 400 to which the nozzle 510 is fixed is in the collection position. Further, the center axes of the two nozzles 510 are provided so as to be parallel to each other in a plan view. As a result, the second liquid can be quickly supplied to the entire upper surface 111 of the rotary body 110. A portion of the second liquid discharged from the nozzle 510 is also supplied to the upper surface of the nozzle head 210.

The supply piping 520 serves as a flow path for sending the liquid to the nozzle 510 from a liquid supply source LT such as a tank in which the liquid is stored. One end of the supply piping 520 is connected to the liquid supply source LT. The other end of the supply piping 520 is connected to the nozzle 510. In the present embodiment, the supply piping 520 is branched into two pieces in order to feed the liquid to the two nozzles 510. That is, the supply piping 520 of the present embodiment is also a piping for distributing the liquid sent from the liquid supply source LT to the two nozzles 510.

The heating portion 530 is a piping heater that heats the liquid passing through the supply piping 520. The heating portion 530 is arranged in the middle of the supply piping 520. In the supply piping 520, the liquid that has passed through the heating portion 530 is heated to become a second liquid (hot water). In addition, the heater 530 may be arranged in the tank of the liquid supply source LT.

The valve 540 is a valve element that switches between discharging and stopping the discharge of the second liquid from the nozzle 510. The valve 540 is arranged in the middle of the supply piping 520 and on an upstream side of the heating portion 530 in a direction in which the liquid flows. By opening the valve 540, the liquid delivered from the liquid source LT is discharged from the nozzle 510. Further, by closing the valve 540, the delivery of the liquid from the liquid source LT to the supply piping 520 is interrupted, and the discharge of the second liquid from the nozzle 510 is stopped.

### Control Device

The control device 600 controls the operation of each portion of the substrate processing apparatus 1. The control device 600 includes a calculation portion and a storage portion. The calculation portion is, for example, a CPU (Central Processing Portion). The storage portion is, for example, a ROM (Read Only Memory). The storage portion stores information necessary for processing the substrate and various control programs for operating the respective portions. In the control device 600, the operation of each portion of the substrate processing apparatus 1 is controlled by the calculation portion reading and executing the control program stored in the storage portion. For example, the control device 600 controls the rotary holding portion 100, the gas supply portion 200, the first liquid supply portion 300, the collecting portion 400, and the second liquid supply portion 500. The control device 600 of the present embodiment controls each portion to execute the cleaning process by the freeze cleaning method on the substrate W. In addition, the control device 600 performs a process of raising the temperature of the upper surface 111 of the rotary body 110 after the substrate W on which the cleaning process is completed is carried out, and then drying the upper surface 111 of the rotary body 110.

### Operation of Substrate Processing Device

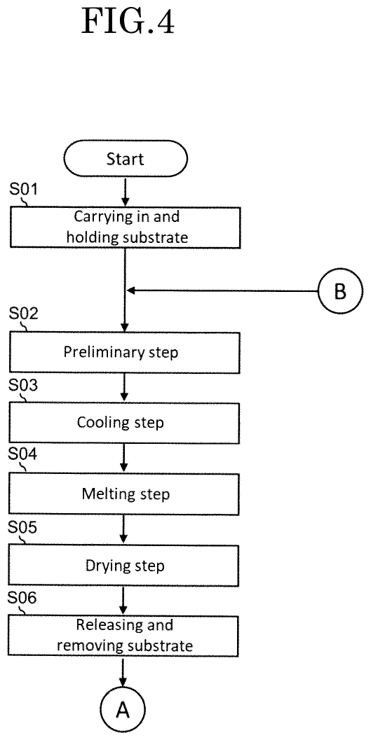

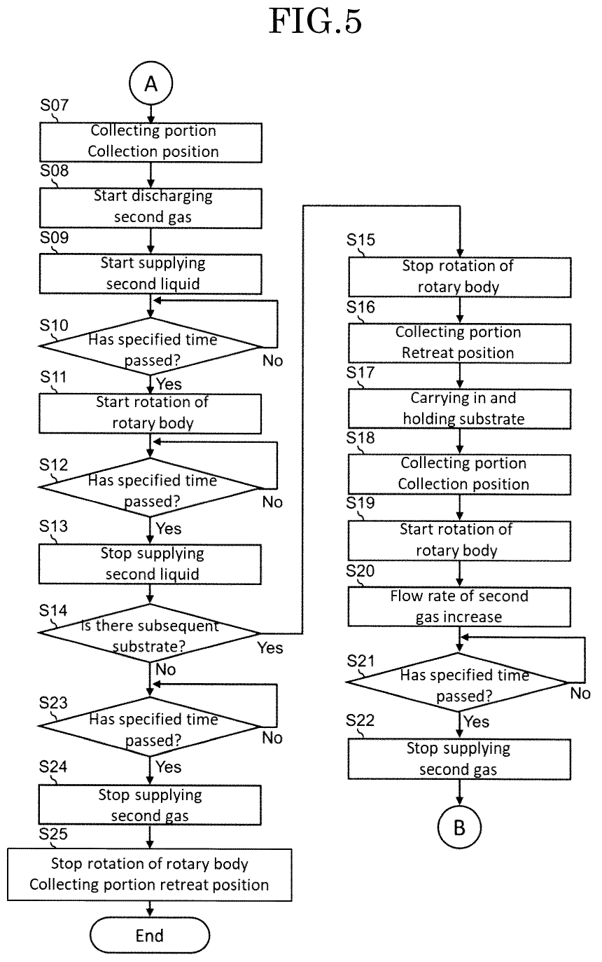

A substrate processing method executed by the substrate processing apparatus 1 as described above will be described with reference to FIG. 4 and FIG. 5 in addition to FIG. 1 to FIG. 3. FIG. 4 and FIG. 5 are flowcharts showing an operation of the substrate processing apparatus 1 according to the first embodiment. The substrate processing apparatus 1 of the present embodiment cleans the substrate W by the cleaning process using the freeze cleaning method.

Before the substrate W is carried into the substrate processing apparatus 1, the discharge nozzle 310 is in a retreat position, and the collecting portion 400 is in a retreat position. Further, the valve 224, the valve 233, the valve 236, and the valve 540 are closed. In this condition, the substrate W held by a hand of a transfer robot is carried above the rotary body 110 and is held by the holding portion 120 (step S01). In addition, the substrate W is carried in a state in which a liquid such as pure water is deposited on the upper surface thereof. The substrate W is held by the holding portion 120, so that the center of the substrate W is positioned so as to coincide with the rotation axis Z. Further, when the hand of the transfer robot retreats to the outside of the substrate processing apparatus 1, the collecting portion 400 is positioned at the collection position.

Next, a freeze cleaning step including a preliminary step, a cooling step (supercooling step+freezing step), a melting step, and a drying step is performed.

In the preliminary step (step S02), the first liquid is supplied to the upper surface of the substrate W and the first liquid on the substrate W and the substrate W are cooled. The control device 600 controls the first liquid supply portion 300 to start the supply of the first liquid to the upper surface of the substrate W. The control device 600 moves the discharge nozzle 310 to the supply position, and then discharges the first liquid from the discharge nozzle 310 toward the upper surface of the substrate W. Further, the control device 600 starts the rotation of the substrate W by controlling the drive portion 130 of the rotary holding portion 100 to rotate the rotary body 110. The first liquid supplied to the upper surface of the substrate W spreads to the outer periphery of the substrate by centrifugal force. Further, the control device 600 controls the gas supply portion 200 to start the supply of the first gas to the space R between the upper surface 111 of the rotary body 110 and the substrate W held by the holding portion 120. The valve 224 is opened under the control of the control device 600, thereby the first gas is discharged from the first discharge port 211 to the space R. By supplying the first gas (cooling gas) to the space R, the substrate W is cooled from a lower surface side. As the substrate W is cooled, the first liquid on the substrate W is also cooled.

In the cooling step (step S03), the liquid film of the first liquid on the substrate W is further cooled and frozen. When the process shifts to the cooling step, the supply of the first liquid by the first liquid supply unit 300 is stopped. Further, the control device 600 controls the drive portion 130 to reduce the rotational speed of the substrate W from the rotational speed of the substrate W in the preliminary step. A rotation speed of the substrate W in the cooling step is set to a rotation speed at which the first liquid supplied to the upper surface of the substrate W is maintained as a liquid film on the upper surface of the substrate W, and is, for example, 30 rpm. In addition, the rotation of the substrate W may be stopped. In the cooling step, the supply of the first gas to the space R by the gas supply portion 200 is continued. As described above, since the first gas is continuously supplied to the space R, the temperature of the liquid film of the first liquid on the substrate W drops below the temperature in the preliminary step, and the liquid film is in a supercooling state (supercooling step).

Even after the liquid film of the first liquid on the substrate W is in the subcooling state, the first gas is continuously supplied to the space R from the gas supply portion 200, so that the temperature of the liquid film is further lowered and at least a part of the liquid film is frozen (freezing step). In the freeze cleaning method, it is generally considered that foreign matter becomes a nucleus, and the supercooled state is removed to start freezing. In the present embodiment, the foreign matter adhering to the upper surface of the substrate W becomes a nucleus and freezes, so that the foreign matter is taken into the ice. In a state in which a liquid and a frozen body are mixed in the middle of a transition from a liquid to a frozen body (ice), it is considered that the frozen body containing foreign matter floats in the liquid. As a result, the foreign matter adhered to the upper surface of the substrate W can be separated from the surface of the substrate W.

In the melting step (step S04), the liquid film frozen on the substrate W is melted. The control device 600 controls the gas supply portion 200 to stop the supply of the first gas. The valve 224 is closed under the control of the control device 600, thereby the discharge of the first gas from the first discharge port 211 is stopped. Further, the control device 600 controls the first liquid supply portion 300 to supply the first liquid to the upper surface of the substrate W. The first liquid is supplied to the upper surface of the substrate W, so that the frozen liquid film is melted. Further, the control device 600 controls the drive portion 130 to increase the rotational speed of the substrate W from the rotational speed of the substrate W in the cooling step. In the present embodiment, the rotational speed is higher than the rotational speed of the substrate W in the preliminary step. By increasing the angular velocity of the substrate W, the melted liquid film together with the supplied first liquid can be easily discharged from the substrate W. In addition, a part of the frozen body on the substrate W may be discharged from the substrate W in a solid state in such a manner that the frozen body is pushed by the first liquid before being melted.

In the drying step (step S05), the substrate W is dried. In the drying step, the control device 600 controls the first liquid supply portion 300 to stop the supply of the first liquid, and moves the discharge nozzle 310 to the retreat position. Further, the control device 600 controls the drive portion 130 to increase the rotational speed of the substrate W from the rotational speed of the substrate W in the melting step. By the rotation of the substrate W, the first liquid on the substrate W is shaken off, and the substrate W can be dried. Further, the angular velocity of the substrate W is higher than in the melting step, so that the substrate W can be dried quickly.

When the substrate W is dried, the substrate W is released and unloaded (step S06). The control device 600 controls the drive portion 130 to stop the rotation of the substrate W. Further, the collecting portion 400 is lowered to be positioned at the retreat position. Thereafter, the hand of the transfer robot enters the inside of the substrate processing apparatus 1. Then, the hand of the transfer robot is released from being held by the holding portion 120 in a state of being inserted under the substrate W. The substrate W held by the hand of the transfer robot is carried out of the substrate processing apparatus 1 by the hand.

Next, an operation of raising the temperature of the rotary body 110 will be described. In the present embodiment, the rotary body 110 is heated and then dried. The process of raising the temperature of the rotary body 110 and the process of drying are collectively referred to as a return process or a return step.

When the substrate W is unloaded, the collecting portion 400 is raised and positioned at the collection position (step S07). As a result, the nozzle 510 fixed to the collecting portion 400 also rises. Further, discharge of the second gas from the first discharge port 211 and the second discharge port 212 is started (step S08). The control device 600 causes the second gas to be discharged from the first discharge port 211 by opening the valve 236, and causes the second gas to be discharged from the second discharge port 212 by opening the valve 233. A flow rate of the second gas discharged from the first discharge port 211 and the second discharge port 212 is a flow rate that prevents the liquid from entering into the first discharge port 211 and the second discharge port 212.

Then, the supply of the second liquid to the upper surface 111 of the rotary body 110 is started (step S09). The control device 600 controls the second liquid supply portion 500 to discharge the second liquid. When the valve 540 is opened, the liquid sent from the liquid source LT is heated by the heater 530 and discharged from the nozzle 510 as the second liquid. The second liquid (for example, hot water) is supplied to the upper surface 111 of the rotary body 110, thereby raising the temperature of the rotary body 110. A part of the second liquid is also supplied to the upper surface of the nozzle head 210. Accordingly, the temperature of the nozzle head 210 is also increased.

As described above, during the preliminary step or the cooling step, the first gas (cooling gas) is supplied to the space R between the upper surface 111 of the rotary body 110 and the substrate W held by the holding portion 120. This lowers the temperature of the rotary body 110. Further, the temperature of the nozzle head 210 also decreases. The temperature of the rotary body 110 and the nozzle head 210 is lower than the normal temperature even after the melting step and the drying step.

In the cooling step, the first gas (cooling gas) supplied to the space R causes a large amount of the gas occupying the space R to become the first gas in the subsequent melting step and drying step. However, when the substrate W is unloaded from the substrate processing apparatus 1, the upper surface 111 of the rotary body 110 and the upper surface of the nozzle head 210 covered with the substrate W are exposed. Therefore, the air above and around the substrate W flows into the upper surface 111 of the rotary body 110 and the upper surface of the nozzle head 210. Further, in order to carry out the substrate W, the hand of the transfer robot enters the substrate processing apparatus 1, so that air also flows from the outside of the substrate processing apparatus 1. Since the air contains moisture, dew condensation occurs when the substrate W is carried out in a state in which the temperature of the rotary body 110 and the temperature of the nozzle head 210 are lowered.

The liquid generated by the dew condensation may be further cooled and frozen to become a frozen body. If the frozen body is generated between the nozzle head 210 and the rotary body 110, a rotation failure in which the rotary body 110 cannot rotate may occur. Alternatively, the load applied to the drive portion 130 that rotates the rotary body 110 increases. Further, if the frozen body is formed around the holding portion 120, rotation of the holding portion 120 (the supporting portion 121) for holding or releasing the substrate W is hindered, and a holding failure of the substrate W may occur.

Therefore, in the present embodiment, the temperature is raised by supplying the second liquid to the upper surface 111 of the rotary body 110 and the upper surface of the nozzle head 210, and the frozen body is melted. As a result, it is possible to prevent the rotation failure and the holding failure caused by the frozen body described above. Further, since the second gas is discharged from the first discharge port 211 and the second discharge port 212, the supplied second liquid is prevented from entering the first discharge port 211 and the second discharge port 212.

The supply of the second liquid continues until a predetermined period of time has elapsed (step S10: No). This predetermined period of time is required for at least a part of the frozen body to melt and become small enough to prevent a rotation failure of the rotary body 110, as determined in advance by an experiment or the like. For example, the predetermined period of time may be a time required for the temperature of the upper surface 111 of the rotary body 110 to reach 0° C. or higher.

If the predetermined period has elapsed (step S10: Yes), the rotary body 110 starts rotating (step S11). By starting the rotation of the rotary body 110 after a predetermined time has elapsed since the supply of the second liquid began, the rotary body 110 is rotated after at least a part of the frozen body is melted. Accordingly, it is possible to suppress the load applied to the drive portion 130 by the frozen body generated between the nozzle head 210 and the rotary body 110. The control device 600 controls the drive portion 130 to rotate the rotary body 110. As the rotary body 110 rotates, the second liquid easily spreads over the entire upper surface 111 of the rotary body 110. Further, discharge of the second liquid supplied to the upper surface 111 of the rotary body 110 and the upper surface of the nozzle head 210 and whose temperature is lowered can be promoted. As a result, the temperature of the rotary body 110 and the nozzle head 210 can be rapidly increased.

The supply of the second liquid to the rotary body 110 continues until a predetermined period of time has elapsed (step S12: No). This predetermined period of time is a period of time in which the temperature of the rotary body 110 and the nozzle head 210 become equal to or higher than the normal temperature, which is obtained in advance by an experiment or the like. By setting the rotary body 110 and the nozzle head 210 to be at room temperature or higher, the dew condensation does not occur after the supply of the second liquid is stopped.

When the predetermined period has elapsed (step S12: Yes), the supply of the second liquid to the upper surface 111 of the rotary body 110 and the upper surface of the nozzle head 210 is stopped (step S13). The control device 600 controls the second liquid supply portion 500 to close the valve 540, thereby stopping the discharge of the second liquid from the nozzle 510.

Next, it is determined whether or not there is a subsequent substrate W to be processed by the substrate processing apparatus 1. If there is a subsequent substrate W (step S14: Yes), the rotation of the rotary body 110 is stopped (step S15). Further, the collecting portion 400 is lowered to be positioned at the retreat position (step S16). Then, the subsequent substrate W held by the hand of the transfer robot is carried into the upper portion of the rotary body 110 and held by the holding portion 120 (step S17). In this case, since the rotary body 110 and the nozzle head 210 are at room temperature or higher, dew condensation does not occur.

When the substrate W is held, the collecting portion 400 is raised and positioned at the collection position (step S18). Then, the rotary body 110 starts rotating (step S19). The control device 600 controls the drive portion 130 to rotate the rotary body 110. As a result, the second liquid remaining on the upper surface 111 of the rotary body 110 or the liquid generated by melting the frozen body moves to the outer periphery of the rotary body 110 by centrifugal force, and is removed.

In step S19, the rotary body 110 rotates, so that the substrate W also rotates. Since the liquid such as pure water on the substrate W is discharged by the rotation, it is preferable to supply the liquid to the upper surface of the substrate W. The control device 600 controls the first liquid supply portion 300 to move the discharge nozzle 310 to the supply position, and then causes the first liquid to be discharged from the discharge nozzle 310 toward the upper surface of the substrate W. Thus, it is possible to prevent the upper surface of the substrate W from being dried while the return process is executed.

Further, the flow rate of the second gas discharged from the first discharge port 211 and the second discharge port 212 is increased (step S20). The controller 600 increases the flow rate of the second gas by changing the opening degrees of the valve 233 and the valve 236. While the substrate W is held, a second gas is ejected from the first discharge port 211 and the second discharge port 212, thereby supplying the second gas to the space R between the upper surface 111 of the rotating body 110 and the substrate W held by the holding portion 120. As a result, in the space R, a gas flow toward an outer peripheral side of the rotary body 110 is generated. The flow of the gas blows away the liquid remaining on the upper surface 111 of the rotary body 110. In this way, the upper surface 111 of the rotary body 110 can be dried.

In particular, the second gas is discharged from the second discharge port 212 toward the center of the substrate W. The second gas discharged from the second discharge port 212 collides with a center of the lower surface of the substrate W, and then flows to the outer peripheral side along the lower surface of the substrate W. Therefore, in the space R, a flow of gas from the center toward the outer periphery is generated. As a result, the liquid remaining on the upper surface of the nozzle head 210 facing the center of the substrate W is also blown away. In this way, the top surface of the nozzle head 210 can also be dried.

The supply of the second gas to the space R continues until a predetermined period of time elapses (step S21: No). This predetermined period of time is a period of time until the liquid remaining on the upper surface 111 of the rotary body 110 and the upper surface of the nozzle head 210 is removed.

When the predetermined period has elapsed (step S21: Yes), the supply of the second gas is stopped (step S22). As a result, the return step of executing the return process is completed. Then, the process returns to step S02, and the freeze cleaning step is performed. In the preliminary step and the cooling step, even if the first gas is supplied to the space R, since the upper surface 111 of the rotary body 110 and the upper surface of the nozzle head 210 are dry, no frozen body is generated in the space R.

On the other hand, in the case where there is no subsequent substrate W (step S14: No), the rotary body 110 continues to rotate until a predetermined period of time has elapsed (step S23: No). Even after the supply of the second liquid is stopped in the step S13, the rotary body 110 continues to rotate, so that the liquid remaining on the upper surface 111 of the rotary body 110 can be removed by centrifugal force. In this case, the control device 600 may control the drive portion 130 to increase the rotational speed of the rotary body 110.

When the predetermined period has elapsed (step S23: Yes), the supply of the second gas is stopped (step S24). The rotation of the rotary body 110 is stopped, and the collecting portion 400 is lowered to be positioned at the retreat position (step S25). Then, the processing by the substrate processing apparatus 1 is ended.

As described above, the substrate processing apparatus 1 according to the first embodiment includes the second liquid supply portion 500 that supplies the second liquid to the upper surface 111 of the rotary body 110 that faces the lower surface of the substrate W and rotates together with the substrate. As a result, since the first gas for cooling is used to cool the substrate W, the second liquid can be supplied to the upper surface 111 of the rotary body 110 whose temperature has decreased. Since the temperature of the second liquid is 0° C. or higher, even if a frozen body is generated in the rotary body 110, the temperature of the rotary body 110 can be raised to melt the frozen body. For example, when a frozen body is formed between the rotary body 110 and a non-rotary member such as the nozzle head 210, a rotation failure may occur in which the rotary body 110 cannot rotate. In addition, when a frozen body is formed around the holding portion 120 (the support portion 121), an operation for holding the substrate W by the holding portion 120 is hindered, and a holding failure of the substrate W may occur. According to the first embodiment, the frozen body can be removed by melting at least a part of the frozen body. As a result, it is possible to suppress the rotation failure of the rotary body 110 caused by the frozen body and the holding failure of the substrate W.

Further, since the second liquid is 0° C. or higher, it is at a temperature equal to or higher than the freezing point of water. By supplying the second liquid to the upper surface 111 of the rotary body 110, the temperature of the rotary body 110 can be raised to 0° C. or higher, and even if dew condensation occurs after the supply of the second liquid is stopped, it is possible to prevent the liquid generated by dew condensation from freezing and generating a frozen body. Therefore, it is possible to suppress the rotation failure of the rotary body 110 and the holding failure of the substrate W.

Further, if the temperature of the second liquid is set to be equal to or higher than the normal temperature, the temperature of the rotary body 110 can be raised to be equal to or higher than the normal temperature by supplying the second liquid to the upper surface 111 of the rotary body 110. By setting the temperature of the rotary body 110 to be equal to or higher than the normal temperature, the occurrence of dew condensation can be prevented. Therefore, it is possible to prevent the occurrence of a frozen body caused by the liquid generated by the dew condensation being frozen.

The substrate processing apparatus 1 according to the first embodiment further includes the second gas supply portion 230 that supplies the second gas, which is a drying gas, to the upper surface 111 of the rotary body 110. Thus, the upper surface 111 of the rotary body 110 supplied with the second liquid can be dried. By removing the liquid remaining on the upper surface 111 of the rotary body 110, it is possible to prevent the remaining liquid from being blown upwards by the supplied first gas and adhering to and contaminating the substrate W when the subsequent substrate W is processed. Further, by drying the upper surface 111 of the rotary body 110, when performing the freeze cleaning process on the subsequent substrate W, the first gas is supplied to the space R which is a space between the upper surface 111 of the rotary body 110 and the substrate W held by the holding portion 120, and even if the rotary body 110 is cooled, it is possible to prevent the frozen body from being generated in the rotary body 110.

The substrate processing apparatus 1 according to the first embodiment supplies the second gas to the upper surface 111 of the rotary body 110 by supplying the second gas to the space R between the upper surface 111 of the rotary body 110 and the substrate W held by the holding portion 120 in a state where the substrate W is held by the holding portion 120. As a result, the second gas can be supplied to the upper surface 111 of the rotary body 110 in a state of being covered with the substrate W via the space R. Since the upper surface 111 of the rotary body 110 is covered with the substrate W via the space R, diffusion of the second gas into the substrate processing apparatus 1 is suppressed, and the second gas can be efficiently supplied to the upper surface 111 of the rotary body 110. Therefore, the upper surface 111 of the rotary body 110 can be dried quickly. In addition, the amount of the second gas used can be suppressed.

The substrate processing apparatus 1 according to the first embodiment further includes the nozzle head 210 having the discharge ports (the first discharge port 211 and the second discharge port 212) through which the second gas is discharged. When the second liquid is supplied to the upper surface 111 of the rotary body 110, the second gas is discharged from the discharge ports (the first discharge port 211 and the second discharge port 212) formed in the nozzle head 210. Accordingly, it is possible to prevent the second liquid from flowing into the discharge port formed in the nozzle head 210. It is possible to prevent the second liquid flowing into the discharge port formed in the nozzle head 210 from being blown upwards when the second gas is discharged, or from being frozen inside the discharge port whose temperature has decreased to block the discharge port.

The substrate processing apparatus 1 according to the first embodiment further includes the control device 600 that controls the rotary holding portion 100 and the second liquid supply portion 500. The control device 600 controls the rotary holding portion 100 and the second liquid supply portion 500 to supply the second liquid to the upper surface 111 of the rotary body 110, and then rotates the rotary body 110. Thus, the liquid remaining on the upper surface 111 of the rotary body 110 can be removed by centrifugal force caused by the rotation of the rotary body 110.

The substrate processing apparatus 1 according to the first embodiment further includes a collecting portion that receives the first liquid discharged from the substrate W held by the holding portion 120. The nozzle 510 (second liquid discharge nozzle) of the second liquid supply portion 500 is fixed to the collecting portion 400. By fixing the nozzle 510 to the collecting portion 400, the nozzle 510 can be arranged close to the upper surface 111 of the rotary body 110, and the second liquid discharged from the nozzle 510 can be prevented from scattering out of the collecting portion 400. Further, by fixing the nozzle 510 to the collecting portion 400, it is easy to arrange the nozzle 510 so that a discharge direction of the nozzle is inclined with respect to the upper surface 111 of the rotary body 110. Since the discharge direction of the nozzle 510 is oblique, an area of the second liquid discharged from the nozzle 510 to be supplied on the upper surface 111 of the rotary body 110 can be increased as compared with the case where the second liquid is discharged perpendicularly to the upper surface 111 of the rotary body 110. Therefore, the frozen body generated on the upper surface 111 of the rotary body 110 can be rapidly melted.

### Second Embodiment

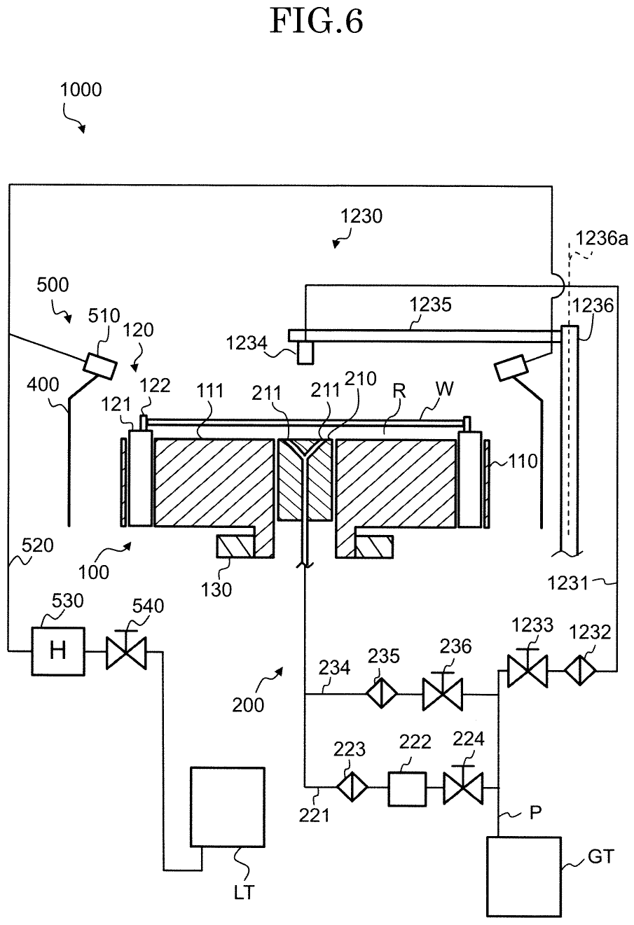

Next, a substrate processing apparatus 1000 according to a second embodiment will be described. FIG. 6 is a side cross-sectional view showing a schematic configuration of the substrate processing apparatus 1000 according to the second embodiment. In the substrate processing apparatus 1000, a configuration of a second gas supply portion is different from the substrate processing apparatus 1 of the first embodiment. In the second embodiment, differences from the first embodiment will be described, and other descriptions will be omitted with the same reference signs.

As shown in FIG. 6, the substrate processing apparatus 1000 according to the second embodiment includes a second gas supply portion 1230. The second gas supply portion 1230 supplies a second gas from above to the upper surface 111 of the rotary body 110. The second gas supply portion 1230 includes a second piping 1231, a removal portion 1232, a valve 1233, a gas discharge nozzle 1234, an arm 1235, and a support pillar 1236. In FIG. 6, the first liquid supply portion 300 and the control device 600 are not shown. In addition, only the first discharge port 211 is formed in the nozzle head 210, and the second discharge port 212 is not formed.

The gas discharge nozzle 1234 discharges the second gas toward the upper surface 111 of the rotary body 110. The second piping 1231 serves as a flow path for sending the gas (second gas) from a gas source GT to the gas discharge nozzle 1234. One end of the second piping 1231 is connected to a common piping P extending from the gas source GT. The other end of the second piping 1231 is connected to the gas discharge nozzle 1234.

The removal portion 1232 is a filter or the like for removing foreign matter contained in the gas passing therethrough. The removal portion 1232 is arranged in the middle of the second piping 1231.

The valve 1233 is a valve element that switches between discharging and stopping the discharging of the second gas from the gas discharge nozzle 1234. The valve 1233 is arranged in the middle of the second piping 1231 and upstream of the removal portion 1232 in a direction in which the gas flows. By opening the valve 1233, the gas (second gas) delivered from the gas source GT is discharged from the gas discharge nozzle 1234. By closing the valve 1233, the delivery of the gas from the gas source GT to the second piping 1231 is interrupted, and the discharge of the second gas from the gas discharge nozzle 1234 is stopped. Further, a flow rate of the second gas discharged from the gas discharge nozzle 1234 can be changed according to a degree of opening of the valve 1233.

The arm 1235 is a rod-shaped member extending in the horizontal direction. The gas discharge nozzle 1234 is fixed to a tip of the arm 1235, and the arm 1235 supports the gas discharge nozzle 1234. The support pillar 1236 is a columnar member extending in the vertical direction. The support pillar 1236 supports the arm 1235 and is rotatably provided with a shaft 1236a as a rotary axis. When the support pillar 1236 is rotated by driving of a drive mechanism (not shown), the arm 1235 is rotated. By the rotation of the arm 1235, the gas discharge nozzle 1234 fixed to the tip of the arm 1235 moves between a supply position above the rotary body 110 and a retreat position, which is a position deviated from an upper part of the rotary body 110. FIG. 6 shows the gas discharge nozzle 1234 in the supply position.

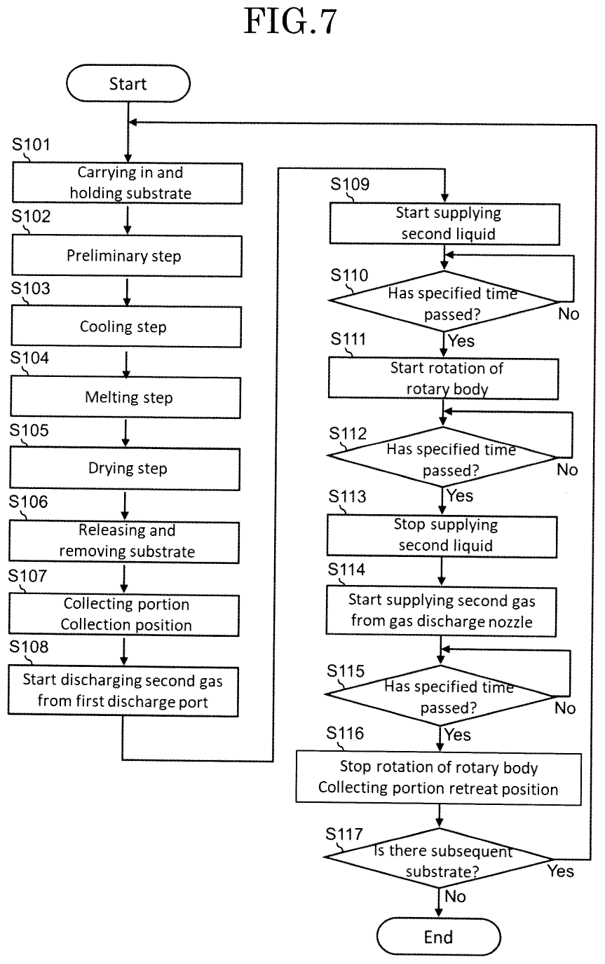

A substrate processing method executed by the substrate processing apparatus 1000 according to the second embodiment will be described with reference to FIG. 7 in addition to FIG. 6. FIG. 7 is a flowchart showing an operation of the substrate processing apparatus 1000 according to the second embodiment. A freeze cleaning step performed in the second embodiment is basically the same as that in the first embodiment, and thus the description thereof will be omitted as appropriate.

Before the substrate W is carried into the substrate processing apparatus 1000, the gas discharge nozzle 1234 is in the retreat position. The valve 1233 is closed. Then, when the substrate W is loaded, a freeze cleaning step including a preliminary step, a cooling step (supercooling step +freezing step), a melting step, and a drying step is performed. Then, the substrate W that has undergone the freeze cleaning process is unloaded. These steps S101 to S106 are the same as steps S01 to S06 described above.

When the substrate W is unloaded, a collection process is performed in which a process of raising the temperature of the upper surface 111 of the rotary body 110 and a process of drying are performed. The process of raising the temperature of the upper surface 111 of the rotary body 110 (step S107 to step S113) is the same as step S07 to step S13 described above. However, in step S108, the second gas may be discharged from the first discharge port 211. It is not necessary to discharge the second gas from the gas discharge nozzle 1234.

When the process of raising the temperature of the upper surface 111 of the rotary body 110 is ended, the gas discharge nozzle 1234 moves to the supply position, and the second gas is discharged to the upper surface 111 of the rotary body 110 (step S114). The control device 600 controls a drive mechanism (not shown) to rotate the support pillar 1236 to move the gas discharge nozzle 1234 to the supply position. Then, the valve 1233 is opened under the control of the control device 600, whereby the second gas is discharged from the gas discharge nozzle 1234. As a result, the second gas is supplied to the upper surface 111 of the rotary body 110. The second gas is also supplied to the upper surface of the nozzle head 210.

While the second gas is being discharged from the gas discharge nozzle 1234, the gas discharge nozzle 1234 is preferably moved so as to be scanned above the rotary body 110. Since the second gas can be supplied to the entire upper surface 111 of the rotary body 110 by the gas discharge nozzle 1234 moving and discharging the gas to the rotating rotary body 110, the upper surface 111 of the rotary body 110 can be dried quickly. In step S114, the control device 600 may control the drive portion 130 to increase a rotation speed of the rotary body 110. By increasing the rotational speed, the liquid remaining on the upper surface 111 of the rotary body 110 can also be removed by centrifugal force.

The supply of the second gas continues until a predetermined period of time elapses (step S115: No). This predetermined period of time is a period of time in which the liquid remaining on the upper surface 111 of the rotary body 110 and the upper surface of the nozzle head 210 can be removed and dried, which is obtained in advance by an experiment or the like.

When the predetermined period has elapsed (step S115: Yes), the supply of the second gas is stopped. The control device 600 controls the gas discharge nozzle 1234 to move to the retreat position after the valve 1233 is closed. Thereafter, the rotation of the rotary body 110 is stopped, and the collecting portion 400 is lowered to be positioned at the retreat position (step S116).

It is determined whether or not there is a subsequent substrate W to be processed by the substrate processing apparatus 1000. If the subsequent substrate W is present (step S117: Yes), the process returns to step S101, and after the subsequent substrate W is loaded, a freeze cleaning step is performed. On the other hand, if there is no subsequent substrate W (step S117: No), the processing by the substrate processing device 1000 is ended.

As described above, according to the substrate processing apparatus 1000 of the second embodiment, as in the first embodiment, the temperature of the rotary body 110 and the nozzle head 210 can be increased, so that at least a part of the frozen body can be melted and the frozen body can be removed. Further, by raising the temperature of the rotary body 110 and the nozzle head 210, even if dew condensation occurs, it is possible to prevent the liquid generated by dew condensation from freezing and generating a frozen body. Therefore, it is possible to suppress a rotation failure of the rotary body 110 and a holding failure of the substrate W caused by the frozen body.

The substrate processing apparatus 1000 according to the second embodiment further includes a gas discharge nozzle 1234 that discharges the second gas toward the upper surface of the rotary body 110. By providing the gas discharge nozzle 1234, the second gas can be supplied toward the upper surface 111 of the rotary body 110 to which the second liquid is supplied. As a result, the upper surface 111 of the rotary body 110 can be dried. Therefore, as in the first embodiment, it is possible to prevent the liquid remaining on the upper surface 111 of the rotary body 110 from adhering to the substrate W or freezing.

Further, according to the second embodiment, since the second gas can be directly supplied toward the upper surface 111 of the rotary body 110, it is easy to dry the upper surface 111 of the rotary body 110 even if there is no substrate W to be subsequently processed. Further, since the second gas can be supplied to the non-rotary member, such as the nozzle head 210, the remaining liquid can be suppressed and the substrate processing apparatus 1000 can be kept clean.

### Modification

The first embodiment and the second embodiment have been described above. However, embodiments of the present disclosure are not limited thereto. For example, the configuration may be as follows.

(1) In the preliminary step, although the first liquid is supplied to the upper surface of the substrate W to form a liquid film, a liquid different from the first liquid may be used. That is, the liquid to be cooled and frozen and the liquid (first liquid) for melting the frozen liquid film in the melting step may be different liquids. In this case, the discharge nozzle 310 may be provided so as to be able to discharge the liquid for forming the liquid film and the first liquid by switching, or a mechanism for supplying the liquid for forming the liquid film to the substrate W may be provided separately from the first liquid supply portion 300.

(2) A plurality of collecting portions 400 may be provided. For example, two collecting portions: a first collecting portion and a second collecting portion are provided. In this case, the first collecting portion is arranged so as to surround the rotary holding portion 100. The second collecting portion is arranged so as to surround the rotary holding portion 100 between the rotary holding portion 100 and the first collecting portion. Each of the first collecting portion and the second collecting portion is provided so as to be movable up and down. In a state in which the first collecting portion is positioned at the collection position, the second collecting portion is raised and lowered so that the collecting portion that receives the liquid can be switched.

The plurality of collecting portions 400 may be provided to switch the collecting portion that receives the liquid between the time when the first liquid is supplied to the substrate W and the time when the second liquid is supplied to the upper surface 111 of the rotary body 110. In this way, the first liquid and the second liquid can be separately collected.

(3) Although the discharge of the second gas from the first discharge port 211 and the second discharge port 212 is started before the second liquid is supplied to the upper surface 111 of the rotary body 110 in order to prevent the second liquid from flowing into the first discharge port 211 and the second discharge port 212, the present disclosure is not limited thereto. For example, except when the first gas (cooling gas) is supplied from the first discharge port 211 to the space R, the second gas may be discharged from the first discharge port 211 and the second discharge port 212 during the operations of the substrate processing apparatuses 1 and 1000.

(4) The substrate processing apparatuses 1 and 1000 are provided with the first piping 221 including the cooling device 222 arranged in the middle, and the third piping 234 connected in the middle of the first piping 221 on a downstream side from the cooling device 222, and are configured so that the gas discharged from the first discharge port 211 can be switched to the first gas and the second gas by opening and closing of the valve 224 and the valve 236, but are not limited thereto. For example, the substrate processing apparatuses 1 and 1000 may be provided with the first piping 221 including the cooling device 222 arranged in the middle, and may be configured so that the gas discharged from the first discharge port 211 can be switched to the first gas and the second gas by driving or stopping driving of the cooling device 222.

(5) The first liquid supply portion 300 and the second liquid supply portion 500 may be combined into one unit. For example, the second liquid may be discharged from the discharge nozzle 310 of the first liquid supply portion 300 to the upper surface 111 of the rotary body 110. Further, the first liquid and the second liquid may be the same liquid. However, the liquid to be supplied to the substrate W is preferably at room temperature or lower for freeze cleaning, and the liquid to be supplied to the upper surface 111 of the rotary body 110 is preferably hot water in order to quickly raise the temperature of the rotary body 110.

(6) In the first embodiment described above, although the nozzle head 210 in which the first discharge port 211 and the second discharge port 212 are formed is used, the present disclosure is not limited thereto. For example, only the first discharge port 211 may be used, as long as the first gas or the second gas can be supplied to the space R. However, when the first gas is supplied toward the center of the substrate W, the center of the substrate W is locally cooled, and freezing does not proceed uniformly. Therefore, it is preferable that the discharge port for discharging the first gas is formed so as to discharge the gas toward a position shifted toward the outer peripheral side from the center of the substrate W.

While certain embodiments have been described, these embodiments have been presented by way of example only, and are not intended to limit the scope of the disclosure. These novel embodiments can be implemented in various other forms, and various omissions, replacements, and modifications can be made without departing from the gist of the disclosure. These embodiments and variations thereof fall within the scope and spirit of the disclosure, and fall within the scope of the disclosure described in the claims and equivalents thereof. Furthermore, the configurations according to the embodiments described above can be appropriately combined as long as there are no mutual contradictions, and technical matters common to the embodiments are included in the respective configurations without explicit description.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A substrate processing apparatus comprising:
a rotary holding portion including a holding portion for holding a substrate and a rotary body having an upper surface facing a bottom surface of the substrate held by the holding portion, the rotary holding portion rotating the substrate by rotating the holding portion and the rotary body;
a first gas supply portion for supplying a first gas for cooling into a space between the upper surface of the rotary body and the substrate held by the holding portion;
a first liquid supply portion for supplying a first liquid to the substrate held by the holding portion; and
a second liquid supply portion for supplying a second liquid having a temperature of 0° C. or higher to the upper surface of the rotary body.

2. The substrate processing apparatus according to claim 1, further comprising a second gas supply portion for supplying a second gas for drying to the upper surface of the rotary body.

3. The substrate processing apparatus according to claim 2, wherein the second gas supply portion supplies the second gas to the upper surface of the rotary body by supplying the second gas into the space between the upper surface of the rotary body and the substrate held by the holding portion while the substrate is held by the holding portion.

4. The substrate processing apparatus according to claim 3, further comprising:
a nozzle head having a discharge port for discharging the second gas; and
a control device for controlling the second liquid supply portion and the second gas supply portion, wherein
the control device controls the second liquid supply portion and the second gas supply portion to discharge the second gas from the discharge port while supplying the second liquid onto the upper surface of the rotary body.

5. The substrate processing apparatus according to claim 2 further comprising a gas discharge nozzle discharging the second gas to the upper surface of the rotary body.

6. The substrate processing apparatus according to claim 1, further comprising a control device for controlling the rotary holding portion and the second liquid supply portion, wherein
the control device controls the rotary holding portion and the second liquid supply portion to rotate the rotary body after supplying the second liquid onto the upper surface of the rotary body.

7. The substrate processing apparatus according to claim 1, further comprising a collecting portion for receiving the first liquid discharged from the substrate held by the holding portion, wherein
the second liquid supply portion includes a second liquid discharge nozzle for discharging the second liquid to the upper surface of the rotary body, and
the second liquid discharge nozzle is fixed to the collecting portion.

8. A substrate processing method comprising:
holding a substrate with a liquid film formed on an upper surface of the substrate so that the substrate faces an upper surface of a rotary body;
supplying a first gas for cooling into a space between the upper surface of the rotary body and the substrate, thereby freezing at least a portion of the liquid film into a frozen body; and
supplying liquid onto the upper surface of the rotary body to raise a temperature of the upper surface of the rotary body.

9. The substrate processing method according to claim 8, wherein after supplying the liquid to the upper surface of the rotary body, a drying gas is supplied to the upper surface of the rotary body.
